(19) United States
(12) Patent Application Publication
(10) Pub. No.: US 2015/0252136 A1
(43) Pub. Date: Sep. 10, 2015

(54) EPOXY RESIN, CURABLE RESIN COMPOSITION, CURED PRODUCT THEREOF, AND PRINTED CIRCUIT BOARD

(71) Applicant: DIC Corporation, Tokyo (JP)

(72) Inventor: Yutaka Satou, Ichihara-shi (JP)

(21) Appl. No.: 14/430,702

(22) PCT Filed: Aug. 29, 2013
(86) PCT No.: PCT/JP2013/073122

§ 371 Date: Mar. 24, 2015

(30) Foreign Application Priority Data
Sep. 25, 2012 (JP) 2012-210948

(51) Int. Cl. C08G 8/36; C08G 59/20; H05K 1/03

(52) U.S. Cl. CPC C08G 8/36; H05K 1/0366; H05K 1/0326; C08G 59/20

(57) ABSTRACT

The preset invention provides a curable resin composition which causes little change in heat resistance after a heat history of cured products and exhibits low thermal expandability, and also provides a cured product of the curable resin composition, a printed circuit board causing little change in heat resistance after a heat history and having excellent low thermal expandability, and an epoxy resin having these performances. The epoxy resin is produced by polyglycidyl-etherification of a reaction product of para-cresol, a β-naphthol compound, and formaldehyde, the epoxy resin containing a trifunctional compound (x) represented by a structural formula (1) below and a dimer (y) represented by a structural formula (2) below, and the content of the trifunctional compound (x) is 55% or more in terms of ratio by area in GPC measurement.

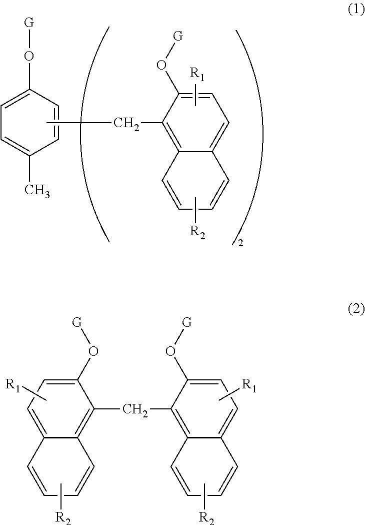

### TECHNICAL FIELD

The present invention relates to an epoxy resin which causes little change in heat resistance of cured products after heat history and has excellent low thermal expandability and which can be preferably used for applications such as a printed circuit board, a semiconductor encapsulating material, a coating material, casting, and the like, and also relates to a cured product of a curable resin composition having these performances and a printed circuit board.

### BACKGROUND ART

Epoxy resins are used for an adhesive, a molding material, a coating material, a photoresist material, a color development material, and the like, and are also widely used for a semiconductor encapsulating material, an insulating material for printed circuit boards, and the like in the electric/electronic field in view of excellent heat resistance and moisture resistance of the resultant cured products.

In the field of printed circuit boards among these applications, the tendency toward higher densities due to narrowing of wiring pitches in semiconductor devices with the tendency toward smaller sizes and higher performance of electronic apparatuses, and a flip-chip bonding method, in which a semiconductor device and a substrate are bonded to each other with solder balls, is widely used as a semiconductor mounting method complying with the tendency. The flip-chip bonding method is a semiconductor mounting method by a so-called reflow method in which solder balls are arranged between a circuit board and a semiconductor and the entire is heated to cause melt-bonding. Therefore, during solder reflowing, the circuit board is exposed to a high-temperature environment, and large stress is applied, due to thermal shrinkage of the circuit board, to the solder balls which connect the circuit board and the semiconductor, thereby causing a connection defect of wiring in some cases. Therefore, insulating materials used for circuit boards are required to be materials having low thermal expansibility.

In addition, according to the regulations to environmental problems, high-melting-point solders not using lead have recently become mainstream, and reflow temperatures have been increased. Accordingly, connection defects which are caused by warping of printed circuit boards due to charge in heat resistance of insulating materials during reflowing have become worse, and thus one of the problems is to suppress change in physical properties during reflowing.

In order to comply with this requirement, for example, a heat-curable resin composition containing, as a main agent, a naphthol novolac-type epoxy resin produced by reacting naphthol with formaldehyde and epichlorohydrin is proposed as one that resolves the technical problem of low thermal expansibility and the like (refer to Patent Literature 1 below).

However, in comparison with general phenol novolac-type epoxy resins, the naphthol novolac-type epoxy resin described above is recognized to have the effect of improving the thermal expansibility of the resultant cured products due to the rigidity of the skeleton, but cannot satisfactorily satisfy a recently required level. Also, the heat resistance of the cured products is greatly changed by a heat history, and thus in the application to printed circuit boards, heat resistance after reflowing is greatly changed, thereby easily causing connection defects in the printed circuit boards.

### CITATION LIST

### Patent Literature

PTL 1: Japanese Examined Patent Application Publication No. 62-20206

### SUMMARY OF INVENTION

### Technical Problem

Therefore, a problem to be solved by the preset invention is to provide a curable resin composition which causes little change in heat resistance of cured products after a heat history and exhibits low thermal expandability, and also provide a cured product of the curable resin composition, a printed circuit board causing little change in heat resistance after heat history and having excellent low thermal expandability, and an epoxy resin having these performances.

### Solution to Problem

As a result of earnest research for resolving the problem, the inventors of the present invention found that an epoxy resin produced by polyglycidyl-etherification of a reaction product of para-cresol, a β-naphthol compound, and formaldehyde, the epoxy resin containing a trifunctional compound with a specified structure and a β-naphthol compound dimer, has excellent solvent solubility, exhibits excellent low thermal expansibility in cured products, and has higher reactivity and smaller change in heat resistance after a heat history, leading to the achievement of the present invention.

That is, the present invention relates to an epoxy resin produced by polyglycidyl-etherification of a reaction product of para-cresol, a β-naphthol compound, and formaldehyde, the epoxy resin containing a trifunctional compound (x) represented by a structural formula (1) below,

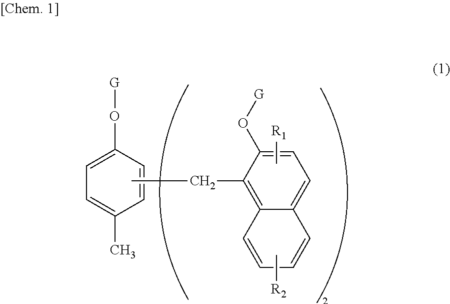

(in the formula, R¹ and R² each independently represent a hydrogen atom, an alkyl group having 1 to 4 carbon atoms, or an alkoxy group having 1 to 4 carbon atoms, and G represents a glycidyl group), and a dimer (y) represented by a structural formula (2) below,

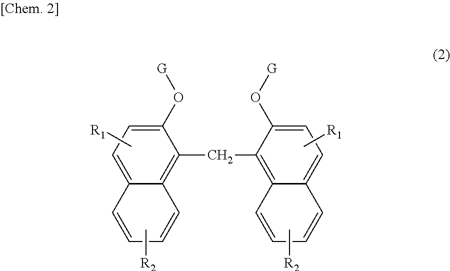

(in the formula, R¹ and R² each independently represent a hydrogen atom, an alkyl group having 1 to 4 carbon atoms, or an alkoxy group having 1 to 4 carbon atoms, and G represents a glycidyl group), and the content of the trifunctional compound (x) is 55% or more in terms of ratio by area in GPC measurement.

Further, the present invention relates to a curable resin composition containing the epoxy resin described above and a curing agent as essential components.

Further, the present invention relates to a cured product produced by curing reaction of the curable resin composition.

Further, the present invention relates to a printed circuit board produced by further mixing an organic solvent with the curable resin composition to prepare a varnish of the resin composition, impregnating a reinforcing base material with the varnish, and laminating a copper foil and heat-pressure bonding the copper foil.

### Advantageous Effects of Invention

According to the present invention, it is possible to provide a curable resin composition which causes little change in heat resistance of cured products after heat history and exhibits low thermal expandability, and also provide a cured product of the curable resin composition, a printed circuit board causing little change in heat resistance after heat history and having excellent low thermal expandability, and an epoxy resin having these performances.

### BRIEF DESCRIPTION OF DRAWINGS

FIG. 1 is a GPC chart of a cresol-naphthol resin (a-1) produced in Example 1.

FIG. 2 is a GPC chart of an epoxy resin (A-1) produced in Example 1.

FIG. 3 is a C¹³NMR chart of the epoxy resin (A-1) produced in Example 1.

FIG. 4 is a MS chart of the epoxy resin (A-1) produced in Example 1.

FIG. 5 is a GPC chart of an epoxy resin (A-2) produced in Example 2.

FIG. 6 is a GPC chart of an epoxy resin (A′-1) produced in Comparative Synthesis Example 1.

### Description of Embodiments

The present invention is described in detail below.

An epoxy resin of the present invention is produced by polyglycidyl-etherification of a reaction product of para-cresol, a β-naphthol compound, and formaldehyde, the epoxy resin containing a trifunctional compound (x) represented by a structural formula (1) below,

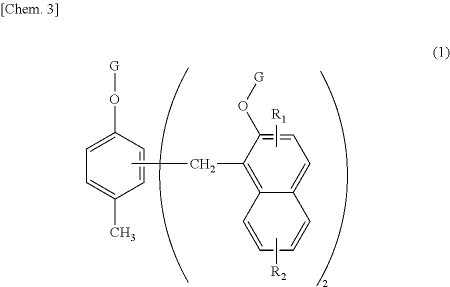

(in the formula, R¹ and R² each independently represent a hydrogen atom, an alkyl group having 1 to 4 carbon atoms, or an alkoxy group having 1 to 4 carbon atoms, and G represents a glycidyl group), and a dimer (y) represented by a structural formula (2) below,

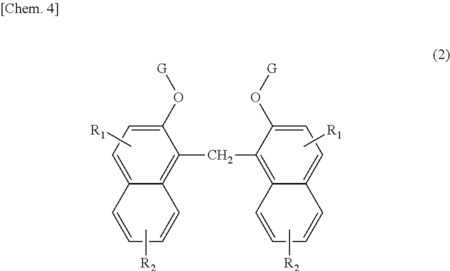

(in the formula, R¹ and R² each independently represent a hydrogen atom, an alkyl group having 1 to 4 carbon atoms, or an alkoxy group having 1 to 4 carbon atoms, and G represents a glycidyl group), and the content of the trifunctional compound (x) is 55% or more in terms of ratio by area in GPC measurement.

That is, the epoxy resin of the present invention is a polyglycidylether of a reaction product of para-cresol, a β-naphthol compound, and formaldehyde used as raw materials, and the epoxy resin is a mixture containing various resin structures which include predetermined amounts of the trifunctional compound (x) and the dimer (y).

The trifunctional compound (x) has a good balance between the concentration of glycidyl group and the concentration of aromatic ring in the molecular structure, and thus increases a crosslink density by improving reactivity of a resin, thereby causing the high effect of suppressing a change in heat resistance after a heat history. However, the trifunctional compound (x) has a cresol skeleton in its molecular structure and thus exhibits excellent solvent solubility and the effect of facilitating preparation of a varnish, but the cured product is not excellent in low thermal expansibility because the cresol skeleton has low orientation. In the present invention, the trifunctional compound (x) is combined with the dimer (y), and the content of the trifunctional compound (x) is adjusted in such a range that the ratio by area in GPC is 55% or more, so that excellent low thermal expansibility can be exhibited without inhibiting the ease of preparation of a varnish. Therefore, the present invention is characterized in that excellent low thermal expansibility can be achieved while the trifunctional compound (x) is contained at a high concentration of 55% or more in terms of ratio by area in GPC and in that a varnish can be easily prepared and excellent low thermal expansibility can be achieved even by using the dimer (y) basically having high molecular orientation and difficulty in preparing a varnish.

As described above, the epoxy resin of the present invention contains the trifunctional compound (x) at a content of 55% or more in terms of ratio by area in GPC measurement, and with the content of less than 55%, the above-described effect of enhancing reactivity and orientation of the resin and the effect of improving solubility are not sufficiently exhibited, thereby producing a cured product causing high thermal expansibility and a large change in heat resistance after a heat history. In particular, the content of the trifunctional compound (x) is preferably in a range of 55% to 95% and more preferably in a range of 60% to 90% in terms of ratio by area in GPC measurement because of the higher effect of decreasing thermal expansibility and a change in heat resistance after a heat history of a cured product.

On the other hand, the content of the dimer (y) in the epoxy resin of the present invention is preferably in a range of 1% to 25% and more preferably in a range of 2% to 15% in terms of ratio by area in GPC measurement because of excellent solvent solubility and a small change in heat resistance after a heat history of the resultant cured product.

In addition, the total content of the trifunctional compound (x) and the dimer (y) in the epoxy resin of the present invention is preferably 60% or more and more preferably 65% or more in terms of ratio by area in GPC measurement because of lower thermal expansibility and a smaller change in heat resistance of the resultant cured product after a heat history.

In the general formula (1) representing the trifunctional compound (x) of the present invention, R¹ and R² each independently represent a hydrogen atom, an alkyl group having 1 to 4 carbon atoms, or an alkoxy group having 1 to 4 carbon atoms, and G represents a glycidyl group. Specific examples of the hexafunctional compound (x) include compounds represented by structural formulae (1-1) to (1-6) below.

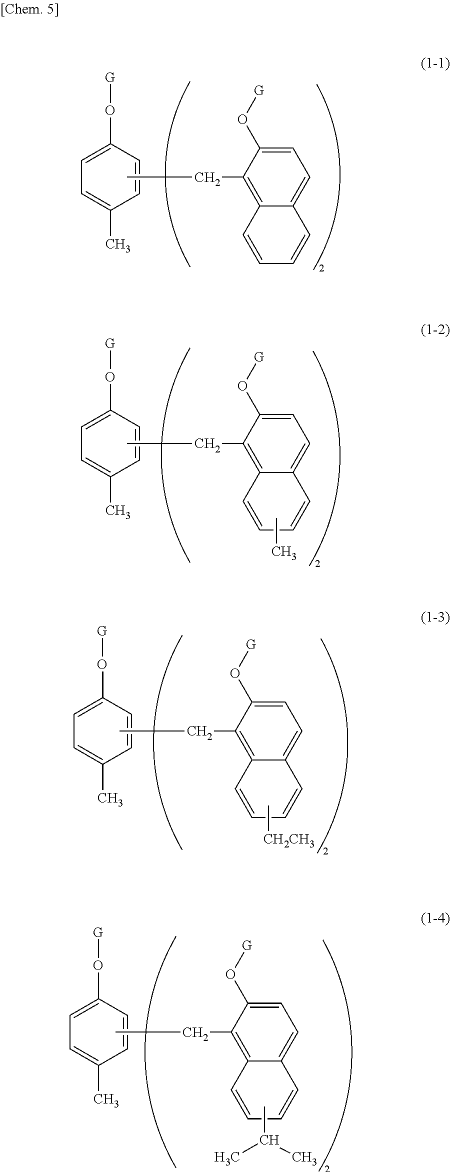

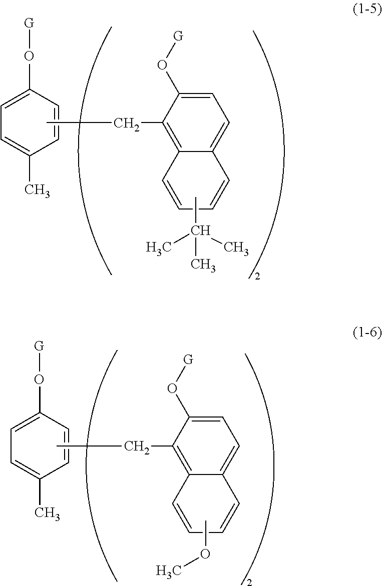

Among these, the compound represented by the structural formula 1-1 in which both of R¹ and R² are hydrogen atoms is particularly preferred in view of a low coefficient of thermal expansion of the cured product.

In addition, in the general formula (2) representing the dimer (y) of the present invention, R¹ and R² each independently represent a hydrogen atom, an alkyl group having 1 to 4 carbon atoms, or an alkoxy group having 1 to 4 carbon atoms, and G represents a glycidyl group. Specific examples of the dimer (y) include compounds represented by structural formulae (2-1) to (2-6) below.

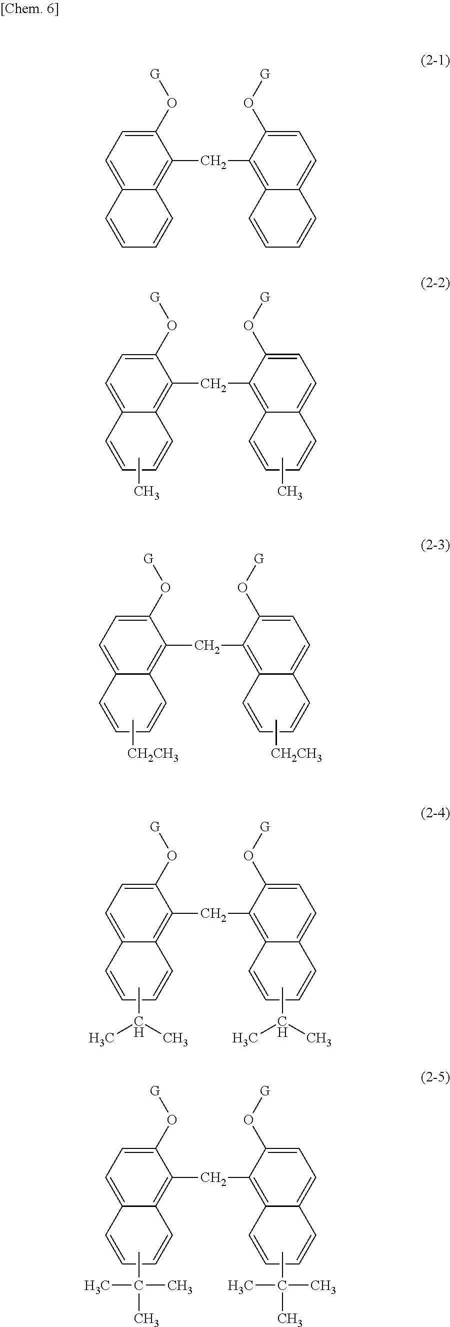

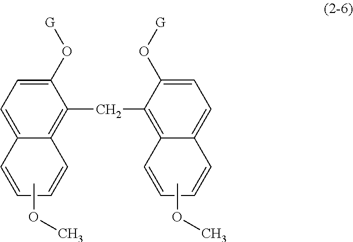

Among these, the compound represented by the structural formula 2-1 in which both of R¹ and R² are hydrogen atoms is particularly preferred in view of a low coefficient of thermal expansion of the cured product.

The content of each of the trifunctional compound (x) and the dimer (y) in the epoxy resin of the present invention is a ratio of a peak area of each of the structures to a total peak area of the epoxy resin of the present invention based on calculation by GPC measurement under conditions described below.

### <GPC Measurement Conditions>

Measuring apparatus: “HLC-8220 GPC” manufactured by Tosoh Corporation

Column: guard column “HXL-L” manufactured by Tosoh Corporation
“TSK-GEL G2000HXL” manufactured by Tosoh Corporation
“TSK-GEL G2000HXL” manufactured by Tosoh Corporation
“TSK-GEL G3000HXL” manufactured by Tosoh Corporation
“TSK-GEL G4000HXL” manufactured by Tosoh Corporation

Detector: RI (differential refractometer)

Data processing: “GPC-8020 model II version 4.10” manufactured by Tosoh Corporation

Measurement condition:
Column temperature 40° C.
Developing solvent tetrahydrofuran
Flow rate 1.0 ml/min

Standard: using monodisperse polystyrene below having a known molecular weight according to a measurement manual of “GPC-8020 model II version 4.10”.

### (Polystyrene Used)

“A-500” manufactured by Tosoh Corporation

“A-1000” manufactured by Tosoh Corporation

“A-2500” manufactured by Tosoh Corporation

“A-5000” manufactured by Tosoh Corporation

“F-1” manufactured by Tosoh Corporation

“F-2” manufactured by Tosoh Corporation

“F-4” manufactured by Tosoh Corporation

“F-10” manufactured by Tosoh Corporation

“F-20” manufactured by Tosoh Corporation

“F-40” manufactured by Tosoh Corporation

“F-80” manufactured by Tosoh Corporation

“F-128” manufactured by Tosoh Corporation

Sample: prepared by filtering with a microfilter a 1.0 mass % tetrahydrofuran solution in terms of resin solid (50 μl).

The epoxy resin of the present invention detailed above preferably has a softening point in a range of 80° C. to 140° C. in view of excellent solvent solubility of the epoxy resin, and more preferably in a range of 85° C. to 135° C. in view of both the low thermal expansibility and a high degree of solvent solubility.

Also, the epoxy resin of the present invention preferably has an epoxy equivalent in a range of 220 to 260 g/eq in view of good low thermal expansibility of the cured product, and particularly preferably in a range of 225 to 255 g/eq.

The epoxy resin of the present invention preferably has a value of molecular weight distribution (Mw/Mn) in a range of 1.00 to 1.50 in view a small change in heat resistance after a heat history of the cured product. In the present invention, the molecular weight distribution (Mw/Mn) is a value calculated from weight-average molecular weight (Mw) and number-average molecular weight (Mn) which are measured under the same conditions as the GPC measurement conditions for determining the contents of the trifunctional compound (x) and the dimer (y).

The epoxy resin of the present invention detailed above can be produced by, for example, a method 1 or method 2 described below.

Method 1: A method including reacting a β-naphthol compound with formaldehyde in the presence of an organic solvent and an alkali catalyst and then adding and reacting para-cresol in the presence of formaldehyde to prepare a cresol-naphthol resin (step 1); and then reacting the resultant cresol-naphthol resin with epihalohydrin (step 2) to produce the target epoxy resin.

Method 2: A method including reacting para-cresol, a β-naphthol compound, and formaldehyde in the presence of an organic solvent and an alkali catalyst to prepare a cresol-naphthol resin (step 1); and then reacting the resultant cresol-naphthol resin with epihalohydrin (step 2) to produce the target epoxy resin.

In the present invention, the method 1 or method 2 uses the alkali catalyst as a reaction catalyst and also uses the organic solvent in a smaller amount relative to the raw material components, and thus the ratios of the trifunctional compound (x) and the dimer (y) present in the epoxy resin can be adjusted in respective proper ranges.

Examples of the alkali catalyst used include alkali metal hydroxides such as sodium hydroxide, potassium hydroxide, and the like; and inorganic alkalis such as metallic sodium, metallic lithium, sodium hydride, sodium carbonate, potassium carbonate, and the like. The amount of use is preferably, on a molar basis, 0.01 to 2.0 times the total number of phenolic hydroxyl groups in the para-cresol and β-naphthol compound used as the raw material components.

In addition, examples of the organic solvent include methyl cellosolve, isopropyl alcohol, ethyl cellosolve, toluene, xylene, methyl isobutyl ketone, and the like. Among these, isopropyl alcohol is particularly preferred from the viewpoint that a polycondensate has a relatively higher molecular weight. The amount of the organic solvent used in the present invention is preferably in a range of 5 70 parts by mass relative to a total mass of 100 parts by mass of the para-cresol and β-naphthol compound used as the raw material components from the viewpoint that the ratio of each of the trifunctional compound (x) and the dimer (y) present in the epoxy resin can be easily adjusted in a predetermined range.

The present invention uses para-cresol as an essential raw material component. By using a para isomer among cresols, the trifunctional compound (x) can be efficiently produced, and the low thermal expansibility of the cured product of the resultant epoxy resin can be improved.

Examples of the β-naphthol compound used as another essential component in the present invention include β-naphthol and a compound produced by nuclear-substitution of the β-naphthol with an alkyl group such as a methyl group, an ethyl group, a propyl group, a tert-butyl group, or the like, an alkoxy group such as a methoxy group, an ethoxy group, or the like. Among these, β-naphthol is preferred in view of a smaller change in heat resistance after a heat history of the cured product of the final resultant epoxy resin.

On the other hand, the formaldehyde used may be a formalin solution in an aqueous solution state or para-formaldehyde in a solid state.

The ratio of the para-cresol to the β-naphthol compound used in the step 1 of the method 1 or method 2 is preferably a molar ratio (para-cresol/β-naphthol compound) within a range of [1/0.5] to [1/4] because the ratio of each of the components in the final resultant epoxy resin can be easily adjusted.

The ratio of the formaldehyde charged in reaction is preferably, on a molar basis, 0.6 to 2 times the total number of moles of the para-cresol and the β-naphthol compound, and particularly preferably 0.6 to 1.5 times in view of excellent low thermal expansibility.

In the step 1 of the method 1, a target polycondensate can be produced by charging predetermined amounts of the β-naphthol compound, formaldehyde, the organic solvent, and the alkali catalyst in a reactor and performing reaction at 40° C. to 100° C., and after the end of the reaction, adding and reacting para-cresol (if required, further adding formaldehyde) under a temperature condition of 40° C. to 100° C.

After the end of the reaction in the step 1, the reaction mixture is neutralized or washed with water until the pH value of the reaction mixture is 4 to 7. Neutralization or washing with water may be performed according to a usual method, and for example, an acid substance such as acetic acid, phosphoric acid, sodium phosphate, or the like can be used as a neutralizing agent. After neutralization or washing with water, the target polycondensate can be produced by distilling off the organic solvent under heating and reduced pressure.

In the step 1 of the method 2, a target polycondensate can be produced by charging predetermined amounts of the β-naphthol compound, para-cresol, formaldehyde, the organic solvent, and the alkali catalyst in a reactor and performing reaction at 40° C. to 100° C.

After the end of the reaction in the step 1, the reaction mixture is neutralized or washed with water until the pH value of the reaction mixture is 4 to 7. Neutralization or washing with water may be performed according to a usual method, and for example, an acid substance such as acetic acid, phosphoric acid, sodium phosphate, or the like can be used as a neutralizing agent. After neutralization or washing with water, the target polycondensate can be produced by distilling off the organic solvent under heating and reduced pressure.

Next, the step 2 of the method 1 or method 2 is a step of producing the target epoxy resin by reacting the polycondensate produced in the step 1 with epihalohydrin. Specifically, the step 2 is performed by a method in which epihalohydrin is added in an amount of 2 to 10 times (molar basis) the number of moles of phenolic hydroxyl groups in the polycondensate and is subjected to reaction at a temperature of 20° C. to 120° C. for 0.5 to 10 hours while further adding at a time or gradually the basic catalyst in an amount of 0.9 to 2.0 times (molar basis) the number of moles of the phenolic hydroxyl groups. The basis catalyst may be used as a solid or an aqueous solution, and when an aqueous solution is used, the method may be performed by continuously adding the catalyst, continuously distilling off water and epihalohydrin from the reaction mixture under reduced pressure or atmospheric pressure, and further removing water by liquid separation and continuously returning epihalohydrin to the reaction mixture.

In industrial production, new epihalohydrin is used in preparation of a first batch for producing an epoxy compound, but in a second batch or later, epihalohydrin recovered from coarse reaction products is preferably combined with new epihalohydrin corresponding to a loss due to the consumption by the reaction. In this case, the epihalohydrin used is not particularly limited, and examples thereof include epichlorohydrin, epibromohydrin, β-methylepichlorohydrin, and the like. In view of industrially easy availability, epichlorohydrin is particularly preferred.

Specific examples of the basic catalyst include alkaline-earth metal hydroxides, alkali metal carbonates, alkali metal hydroxides, and the like. In view of excellent catalyst activity in epoxy resin synthesis reaction, alkali metal hydroxides are particularly preferred, and examples thereof include sodium hydroxide, potassium hydroxide, and the like. When used, the basic catalyst may be used in the form of an aqueous solution of about 10% to 55% by mass or may be used in a solid form. In addition, the reaction rate of synthesis of an epoxy compound can be increased by combining an organic solvent. Examples of the organic solvent include, but are not particularly limited to, ketones such as acetone, methyl ethyl ketone, and the like; alcohol compounds such as methanol, ethanol, 1-propylalcohol, isopropyl alcohol, 1-butanol, secondary butanol, tertiary butanol, and the like; cellosolves such as methyl cellosolve, ethyl cellosolve, and the like; ether compounds such as tetrahydrofuran, 1,4-dioxane, 1,3-dioxane, diethoxyethane, and the like; and aprotic polar solvents such as acetonitrile, dimethylsulfoxide, dimethylformamide, and the like. These organic solvents may be used alone or in appropriate combination of two or more in order to adjust polarity.

The product of the epoxidation reaction is washed with water and then unreacted epihalohydrin and the organic solvent combined are distilled off by distillation under heating and reduced pressure. Further, in order to produce an epoxy resin containing little hydrolyzable halogen, the resultant epoxy resin can be dissolved again in an organic solvent such as toluene, methyl isobutyl ketone, methyl ethyl ketone, or the like, and an aqueous solution of an alkali meta hydroxide such as sodium hydroxide, potassium hydroxide, or the like can be added to the resultant solution and subjected to further reaction. In this case, a phase transfer catalyst such as a quaternary ammonium salt, crown ether, or the like may be present for the purpose of improving the reaction rate. When the phase transfer catalyst is used, the amount of use is preferably a ratio of 0.1 to 3.0 parts by mass relative to 100 parts by mass of the epoxy resin used. After the finish of the reaction, the produced salt is removed by filtration and washing with water, and further the solvent such as toluene, methyl isobutyl ketone, or the like is removed by distillation under heating and reduced pressure, whereby the target novel epoxy compound of the present invention can be produced.

Next, a curable resin composition of the present invention contains the epoxy resin detailed above and a curing agent as essential components.

Examples the curing agent used include amine compounds, amide compounds, acid anhydride compounds, phenol compounds, and the like. Specific examples of the amine compounds include diaminodiphenylmethane, diethylene triamine, triethylene tetramine, diaminodiphenyl sulfone, isophorone diamine, imidazole, BF₃-amine complex, guanidine derivatives, and the like. Examples of the amide compounds include dicyandiamide, polyamide resin synthesized by a linolenic acid dimer and ethylenediamine, and the like. Examples of the acid anhydride compounds include phthalic anhydride, trimellitic anhydride, pyromellitic anhydride, maleic anhydride, tetrahydrophthalic anhydride, methyltetrahydrophthalic anhydride, methylnadic anhydride, hexahydrophthalic anhydride, methylhexahydrophthalic anhydride, and the like. Examples of the phenol compounds include polyhydric phenol compounds such as phenol novolac resins, cresol novolac resins, aromatic hydrocarbon formaldehyde resin-modified phenol resins, dicyclopentadiene phenol-added resins, phenol aralkyl resins (Xyloc resins), polyhydric phenol novolac resins represented by resorcin novolac resins, which are synthesized from polyhydric hydroxyl compounds and formaldehyde, naphthol aralkyl resins, trimethylol methane resins, tetraphenylol ethane resins, naphthol novolac resins, naphthol-phenol condensed novolac resins, naphthol-cresol condensed novolac resins, biphenyl-modified phenol resins (polyhydric phenol compounds in which phenol nuclei are connected through a bismethylene group), biphenyl-modified naphthol resins (polyhydric naphthol compounds in which phenol nuclei are connected through a bismethylene group), aminotriazine-modified phenol resins (polyhydric phenol compounds in which phenol nuclei are connected with melamine or benzoguanamine), alkoxy group-containing aromatic ring-modified novolac resins (polyhydric phenol compounds in which phenol nuclei and alkoxy group-containing aromatic rings are connected through formaldehyde), and the like.

Among these, a compound having many aromatic skeletons in its molecular structure is particularly preferred in view of low thermal expansibility. Specifically, in view of low thermal expansibility, preferred are phenol novolac resins, cresol novolac resins, aromatic hydrocarbon formaldehyde resin-modified phenol resins, phenol aralkyl resins, resorcin novolac resins, naphthol aralkyl resins, naphthol novolac resins, naphthol-phenol condensed novolac resins, naphthol-cresol condensed novolac resins, biphenyl-modified phenol resins, biphenyl-modified naphthol resins, aminotriazine-modified phenol resins, and alkoxy group-containing aromatic ring-modified novolac resins (polyhydric phenol compounds in which phenol nuclei and alkoxy group-containing aromatic rings are connected through formaldehyde).

The amounts of the epoxy resin and curing agent mixed in the curable resin composition of the present invention are not particularly limited, but in view of the good characteristics of the resultant cured product, the amount of active groups in the curing agent is preferably 0.7 to 1.5 equivalents relative to a total of 1 equivalent of epoxy groups in the epoxy resin.

If required, the curable resin composition of the present invention can be properly combined with a curing accelerator. Various compounds can be used as the curing accelerator, and examples thereof include phosphorus-based compounds, tertiary amines, imidazole, organic acid metal salts, Lewis acids, amine complex salts, and the like. In particular, in use for application to a semiconductor encapsulating material, triphenylphosphine as a phosphorus-based compound and 1,8-diazabicyclo-[5.4.0]-undecene (DBU) as a tertiary amine are preferred in view of excellent curability, heat resistance, electric characteristics, moisture-resistance reliability, and the like.

The epoxy resin of the present invention described above may be singly used as an epoxy resin component in the curable resin composition of the present invention, but the epoxy resin of the present invention may be combined with another epoxy resin within a range where the effect of the present invention is not impaired. Specifically, the other epoxy resin can be used in such a range that the amount of the epoxy resin of the present invention is 30% by mass or more and preferably 40% by mass or more relative to the total mass of the epoxy resin component.

Examples of the other epoxy resin which can be used in combination with the epoxy resin described above include various epoxy resins such as bisphenol A-type epoxy resins, bisphenol F-type epoxy resins, biphenyl-type epoxy resins, tetramethylbiphenyl-type epoxy resins, phenol novolac-type epoxy resins, cresol novolac-type epoxy resins, bisphenol A novolac-type epoxy resins, triphenylmethane-type epoxy resins, tetraphenylethane-type epoxy resins, dicyclopentadiene-phenol addition reaction-type epoxy resins, phenol aralkyl-type epoxy resins, naphthol novolac-type epoxy resins, naphthol aralkyl-type epoxy resins, naphthol-phenol condensed novolac-type epoxy resins, aromatic hydrocarbon formaldehyde resin-modified phenol resin-type epoxy resins, biphenyl novolac-type epoxy resins, and the like. From the viewpoint that cured products having excellent heat resistance can be produced, particularly preferred among these are phenol aralkyl-type epoxy resins, biphenyl novolac-type epoxy resins, naphthol novolac-type epoxy resins having a naphthalene skeleton, naphthol aralkyl-type epoxy resins, naphthol-phenol condensed novolac-type epoxy resins, crystalline biphenyl-type epoxy resins, tetramethylbiphenyl-type epoxy resins, xanthene-type epoxy resins, alkoxy group-containing aromatic ring-modified novolac-type epoxy resins (compounds in which glycidyl group-containing aromatic rings and alkoxy group-containing aromatic rings are connected through formaldehyde), and the like.

The curable resin composition of the present invention detailed above is characterized by exhibiting excellent solvent solubility and can be mixed with an organic solvent besides the components described above. Examples of the organic solvent which can be used include methyl ethyl ketone, acetone, dimethylformamide, methyl isobutyl ketone, methoxypropanol, cyclohexanone, methyl cellosolve, ethyl diglycol acetate, propylene glycol monomethyl ether acetate, and the like. The organic solvent used and appropriate amount thereof can be properly selected according to application. For example, in application to a printed circuit board, a polar solvent having a boiling point of 160° C. or less, such as methyl ethyl ketone, acetone, dimethylformamide, or the like is preferred, and the solvent is preferably used so that a nonvolatile component ratio is 40% to 80% by mass. In addition, in application to an adhesive film for build-up, examples of the organic solvent which can be preferably used include ketones such as acetone, methyl ethyl ketone, cyclohexanone, and the like; acetates such as ethyl acetate, butyl acetate, cellosolve acetate, propylene glycol monomethyl ether acetate, carbitol acetate, and like; carbitols such as cellosolve, butyl carbitol, and the like; aromatic hydrocarbons such as toluene, xylene, and the like; dimethylformamide; dimethylacetamide, N-methylpyrrolidone, and the like, and the solvent is preferably used so that a nonvolatile component ratio is 30% to 60% by mass.

Also, for example, in the field of printed circuit boards, in order to exhibit flame retardancy, the curable resin composition may be mixed with a non-halogen flame retardant substantially not containing halogen atoms within a range in which reliability is not degraded.

Examples of the non-halogen flame retardant include a phosphorus-based flame retardant, a nitrogen-based flame retardant, a silicone-based flame retardant, an inorganic flame retardant, an organic metal salt-based flame retardant, and the like, and the use thereof is not particularly limited. These flame retardants may be used alone or in combination of a plurality of same types or different types of flame retardants.

Either an inorganic or organic compound can be used as the phosphorus-based flame retardant. Examples of the inorganic compound include red phosphorus, ammonium phosphates such as monoammonium phosphate, diammonium phosphate, triammonium phosphate, polyammonium phosphate, and the like; inorganic nitrogen-containing phosphorus compounds such as phosphoric acid amide and the like.

Also, red phosphorus is preferably surface-treated for the purpose of preventing hydrolysis or the like, and examples of a surface treatment method include (i) a method of coating with an inorganic compound such as magnesium hydroxide, aluminum hydroxide, zinc hydroxide, titanium hydroxide, bismuth oxide, bismuth hydroxide, bismuth nitrate, or a mixture thereof, (ii) a method of coating with a mixture of an inorganic compound such as magnesium hydroxide, aluminum hydroxide, zinc hydroxide, or titanium hydroxide, and a thermosetting resin such as a phenol resin or the like; and (iii) a method of double-coating with an inorganic compound such as magnesium hydroxide, aluminum hydroxide, zinc hydroxide, titanium hydroxide, or the like and further coating with a thermosetting resin such as a phenol resin or the like.

Examples of the organic phosphorus compound include general-purpose organic phosphorus-based compounds such as phosphoric acid ester compounds, phosphonic acid compounds, phosphinic acid compounds, phosphine oxide compounds, phosphorane compounds, organic nitrogen-containing phosphorus compounds, and the like; cyclic organic phosphorus compounds such as 9,10-dihydroxy-9-oxa-10-phosphaphenanthrene-10-oxide, 10-(2,5-dihydroxyphenyl)-10H-9-oxa-10-phosphaphenanthrene-10-oxide, 10-(2,7-dihydroxynaphthyl)-10H-9-oxa-10-phosphaphenanthrene-10-oxide, and the like; and derivatives produced by reacting the cyclic organic phosphorus compounds with a compound such as an epoxy resin, a phenol resin, or the like.

The amount of the phosphorus-based flame retardant mixed is properly selected according to the type of the phosphorus-based flame retardant, the other components of the curable resin composition, and the degree of desired flame retardancy. For example, when red phosphorus is used as the non-halogen flame retardant, it is preferably mixed within a range of 0.1 to 2.0 parts by mass in 100 parts by mass of the curable resin composition containing all of the epoxy resin, the curing agent, the non-halogen flame retardant, and the filler and other additives, and when the organic phosphorus compound is used, it is preferably mixed within a range of 0.1 to 10.0 parts by mass and particularly preferably within a range of 0.5 to 6.0 parts by mass, in 100 parts by mass of the curable resin composition.

When the phosphorus-based flame retardant is used, the phosphorus-based flame retardant may be combined with hydrotalcite, magnesium hydroxide, a boron compound, zirconium oxide, a black dye, calcium carbonate, zeolite, zinc molybdate, activated carbon, or the like.

Examples of the nitrogen-based flame retardant include a triazine compound, a cyanuric acid compound, an isocyanuric acid compound, phenothiazine, and the like, and a triazine compound, a cyanuric acid compound, and an isocyanuric acid compound are preferred.

Examples of the triazine compound include melamine, acetoguanamine, benzoquanamine, melon, melam, succinoguanamine, ethylenedimelamine, polymelamine phosphate, triguanamine, and the like. Other examples include (i) aminotriazine sulfate compounds such as guanylmelamine sulfate, melem sulfate, melam sulfate and the like; (ii) co-condensates of phenols, such as phenol, cresol, xylenol, butylphenol, nonylphenol, or the like, melamines such as melamine, benzoquanamine, acetoguanamine, formguanamine, or the like, and formaldehyde; (iii) mixtures of the co-condensates (ii) and a phenol resin such as phenol-formaldehyde condensate or the like, and (iv) compounds prepared by further modifying the compound (ii) or (iii) with tung oil, isomerized linseed oil, or the like.

Examples of the cyanuric acid compound include cyanuric acid, melamine cyanurate, and the like.

The amount of the nitrogen-based flame retardant mixed is properly selected according to the type of the nitrogen-based flame retardant, the other components of the curable resin composition, and the degree of desired flame retardancy. For example, the nitrogen-based flame retardant is preferably mixed within a range of 0.05 to 10 parts by mass and particularly preferably within a range of 0.1 to 5 parts by mass in 100 parts by mass of the curable resin composition containing all of the epoxy resin, the curing agent, the non-halogen flame retardant, and the filler and other additives.

Also, when the nitrogen-based flame retardant is used, it may be combined with a metal hydroxide, a molybdenum compound, or the like.

The silicone-based flame retardant is not particularly limited as long as it is an organic compound containing a silicon atom, and examples thereof include silicone oil, silicone rubber, silicone resin, and the like.

The amount of the silicone-based flame retardant mixed is properly selected according to the type of the silicone-based flame retardant, the other components of the curable resin composition, and the degree of desired flame retardancy. For example, the silicone-based flame retardant is preferably mixed within a range of 0.05 to 20 parts by mass in 100 parts by mass of the curable resin composition containing all of the epoxy resin, the curing agent, the non-halogen flame retardant, and other additive such as the filler. Also, when the silicone-based flame retardant is used, it may be combined with a molybdenum compound, alumina, or the like.

Examples of the inorganic flame retardant include metal hydroxides, metal oxides, metal carbonate compounds, metal powders, boron compounds, low-melting-point glass, and the like.

Specific examples of the metal hydroxides include aluminum hydroxide, magnesium hydroxide, dolomite, hydrotalcite, calcium hydroxide, barium hydroxide, zirconium hydroxide, and the like.

Specific examples of the metal oxides include zinc molybdate, molybdenum trioxide, zinc stannate, tin oxide, aluminum oxide, iron oxide, titanium oxide, manganese oxide, zirconium oxide, zinc oxide, molybdenum oxide, cobalt oxide, bismuth oxide, chromium oxide, nickel oxide, copper oxide, tungsten oxide, and the like.

Specific examples of the metal carbonate compounds include zinc carbonate, magnesium carbonate, calcium carbonate, barium carbonate, basic magnesium carbonate, aluminum carbonate, iron carbonate, cobalt carbonate, titanium carbonate, and the like.

Specific examples of the metal powders include powders of aluminum, iron, titanium, manganese, zinc, molybdenum, cobalt, bismuth, chromium, nickel, copper, tungsten, tin, and the like.

Specific examples of the boron compounds include zinc borate, zinc metaborate, barium metaborate, boric acid, borax, and the like.

Specific examples of the low-melting-point glass include glassy compounds such as CEEPREE (Bokusui Brown Co., Ltd.), hydrate glass SiO₂—MgO—H₂O, PbO—B₂O₃—, ZnO—P₂O₅—MgO—, P₂O₅—B₂O₃—PbO—MgO—, P—Sn—O—F—, PbO—V₂O₅—TeO₂—, and Al₂O₃—H₂O—based and lead borosilicate-based glass.

The amount of the inorganic flame retardant mixed is properly selected according to the type of the inorganic flame retardant, the other components of the curable resin composition, and the degree of desired flame retardancy. For example, the inorganic flame retardant is preferably mixed within a range of 0.05 to 20 parts by mass and particularly preferably in a range of 0.5 to 15 parts by mass in 100 parts by mass of the curable resin composition containing all of the epoxy resin, the curing agent, the non-halogen flame retardant, and other additive such as the filler.

Examples of the organic metal salt-based flame retardant include ferrocene, acetylacetonate metal complexes, organic metal carbonyl compounds, organic cobalt salt compounds, organic sulfonic acid metal salts, compounds each having ionic bond or coordinate bond between a metal atom and an aromatic compound or a heterocyclic compound, and the like.

The amount of the organic metal salt-based flame retardant mixed is properly selected according to the type of the organic metal salt-based flame retardant, the other components of the curable resin composition, and the degree of desired flame retardancy. For example, the organic metal salt-based flame retardant is preferably mixed within a range of 0.005 to 10 parts by mass in 100 parts by mass of the curable resin composition containing all of the epoxy resin, the curing agent, the non-halogen flame retardant, and the filler and other additives.

If required, the curable resin composition of the present invention can be mixed with an inorganic filler. Examples of the inorganic filler include fused silica, crystalline silica, alumina, silicon nitride, aluminum hydroxide, and the like. When the amount of the inorganic filler mixed is particularly increased, fused silica is preferably used. The fused silica can be used in either a crushed shape or a spherical shape, but the spherical shape is mainly preferably used for increasing the amount of the fused silica mixed in increased and suppressing an increase in melt viscosity of a molding material. Further, in order to increase the amount of spherical silica mixed, the grain size distribution of the spherical silica is preferably properly adjusted. The filling rate is preferably as high as possible in view of flame retardancy, and is particularly preferably 20% by mass or more relative to the total amount of the curable resin composition. Also, in the use for application to a conductive paste, a conductive filler such as a silver powder, a copper powder, or the like can be used.

If required, various compounds such as a silane coupling agent, a mold release agent, a pigment, an emulsifier, and the like can be added to the curable resin composition of the present invention.

The curable resin composition of the present invention can be produced by uniformly mixing the components described above. The curable resin composition of the present invention containing the epoxy resin of the present invention, the curing agent, and if required, further the curing accelerator can be easily formed into a cured product by the same method as a generally known method. Examples of the cured product include molded cured products such as a laminate, a casting, an adhesive layer, a coating film, a film, and the like.

Examples of applications using the curable resin composition of the present invention include printed circuit board materials, resin casting materials, adhesives, interlayer insulating materials for build-up substrates, adhesive films for build-up, and the like. Among these applications, in the application to insulating materials for printed circuit boards and electronic circuit boards, and adhesive films for build-up, the curable resin composition can be used as an insulating material for a so-called substrate for built-in electronic components, in which a passive component such as a capacitor and an active component such as an IC chip are embedded in the substrate. In particular, the curable resin composition is preferably used for printed circuit board materials and adhesive films for build-up in view of the characteristics such as small change in heat resistance after a heat history, low thermal expansibility, and solvent solubility.

By using the curable resin composition of the present invention, a printed circuit board can be produced by, for example, a method including impregnating a reinforcing base material with a varnish of the curable resin composition containing the organic solvent and then laminating a copper foil and pressure-heat bonding the copper foil. Examples of the reinforcing base material which can be used include paper, a glass cloth, a glass nonwoven fabric, aramid paper, aramid cloth, a glass mat, a glass roving cloth, and the like. In further detail, the method includes heating the varnish-like curable resin composition described above at a heating temperature according to the type of the solvent used, preferably at 50° C. to 170° C., to prepare a prepreg as a cured product. The mass ratio between the resin composition and the reinforcing base material is not particularly limited but is generally preferably adjusted so that the resin content in the prepreg is 20% to 60% by mass. Next, the prepregs prepared as described above are properly stacked by a usual method, and a copper foil is laminated and heat-pressure-bonded at 170° C. to 250° C. for 10 minutes to 3 hours under a pressure of 1 to 10 MPa, thereby producing a target printed circuit board.

When the curable resin composition of the present invention is used as a resist ink, for example, a method can be used, in which a cationic polymerization catalyst is used as the curing agent of the curable resin composition, a pigment, talc, and a filler are further added to the curable resin composition to prepare a composition for a resist ink, and then the composition is applied to a printed board by a screen printing method and cured to form a resist ink cured product.

When the curable resin composition of the present invention is used as a conductive paste, for example, a method can be used, in which a composition for an anisotropic conductive film is prepared by dispersing fine conductive particles in the curable resin composition or in which a paste resin composition for circuit connection or anisotropic conductive adhesive which is liquid at room temperature is prepared.

An example of a method for producing an interlayer insulating material for a build-up substrate by using the curable resin composition of the present invention includes applying the curable resin composition properly containing rubber, a filler, or the like to a circuit board, on which a circuit is formed, by a spray coating method, a curtain coating method, or the like, and then curing the resin composition. Then, if required, holes such as predetermined through holes are formed, and then the surface is treated with a roughening agent and washed with hot water to form irregularity, followed by plating with a metal such as copper or the like. The plating method is preferably electroless plating, electroplating, or the like, and an oxidizer, an alkali, an organic solvent, or the like can be used as the roughening agent. This operation is successively repeated according to demand to alternately build-up a resin insulating layer and a conductor layer having a predetermined circuit, so that a build-up substrate can be produced. However, the through holes are formed after the outermost resin insulating layer is formed. Also, a build-up substrate can be produced, without the plating step, by heat-pressure-bonding at 170° C. to 250° C. a copper foil with a resin, which is formed by semi-cuing the resin composition on the copper foil, to a circuit substrate having a circuit formed thereon, thereby forming a roughened surface.

An example of a method for producing an adhesive film for build-up using the curable resin composition of the present invention is a method in which the curable resin composition of the present invention is applied to a support film to form a resin composition layer, thereby forming an adhesive film for a multilayered printed circuit board.

When the curable resin composition of the present invention is used for the adhesive film for build-up, it is necessary for the adhesive film to soften under a lamination temperature condition (generally 70° C. to 140° C.) in a vacuum lamination method and exhibit mobility (resin flow) enabling resin filling in via holes or through holes present in a circuit board at the same time as lamination on the circuit board. The components described above are preferably mixed so as to exhibit these characteristics.

The through holes of the multilayered printed circuit board generally have a diameter of 0.1 to 0.5 mm and a depth of 0.1 to 1.2 mm, and in general, filling of the resin can be preferably performed within this range. When both sides of the circuit board are laminated, the through holes are preferably about ½ filled.

Specifically, the adhesive film can be produced by a method including preparing a varnish of the curable resin composition of the present invention, applying the varnish-like composition on a surface of a support film (Y), and further drying the organic solvent by heating or hot air spraying to form a layer (X) of the curable resin composition.

The thickness of the formed layer (X) is generally equal to or larger than the thickness of a conductor layer. Since the thickness of the conductor layer possessed by the circuit board is generally within a range of 5 to 70 μm, the thickness of the resin composition layer is preferably 10 to 100 μm.

In addition, the layer (X) according to the present invention may be protected by a protective film described below. By protecting by the protective film, dust adhesion and flaws on the surface of the resin composition layer can be prevented.

Examples of the support film and the protective film include films of polyolefins such as polyethylene, polypropylene, polyvinyl chloride, and the like, polyesters such as polyethylene terephthalate (may be abbreviated as “PET” hereinafter), polyethylene naphthalate, and the like, polycarbonate, and polyimide; release paper; metal foils such as a copper foil, an aluminum foil, and the like. The support film and the protective film may be subjected treatment such as MAD treatment, corona treatment, or mold release treatment.

The thickness of the support film is not particularly limited but is generally within a range of 10 to 150 μm and preferably 25 to 50 μm. The thickness of the protective film is preferably 1 to 40 μm.

The support film (Y) is separated after laminated on the circuit board or after an insulating layer is formed by heat curing. When the support film (Y) is separated after the adhesive film is heat-cured, adhesion of dust or the like can be prevented in the curing step. When separated after curing, the support film is generally previously subjected to mold release treatment.

Next, by using the adhesive film formed as described above, the multilayered printed circuit board is produced by a method in which for example, when the layer (X) is protected by the protective film, the protective film is separated, and then the layer (X) is laminated on one or both of the sides of the circuit board by, for example, a vacuum lamination method so that the layer (X) is in direct contact with the circuit board. The lamination method may be either a batch method or a continuous method using a roll. In addition, if required, the adhesive film and the circuit board may be heated (pre-heated) before lamination.

The lamination conditions preferably include a pressure-bonding temperature (lamination temperature) of 70° C. to 140° C. and a pressure-bonding pressure of 1 to 11 kgf/cm² (9.8×104 to 107.9×10⁴ N/m2), and lamination is preferably performed under reduced pressure at an air pressure of 20 mmHg (26.7 hPa) or less.

A cured product of the present invention may be produced according to a general method for curing a curable resin composition. For example, a heating temperature condition may be properly selected according to the type of the curing agent combined and application, but the composition prepared by the method described above may be heated within a temperature range of about 20° C. to 250° C.

Therefore, by using the epoxy resin, solvent solubility of an epoxy resin is significantly improved, and a cured product formed using the epoxy resin causes little change in heat resistance after a heat history and can exhibit low thermal expansibility and can be applied to leading-edge printed circuit board materials. Also, the epoxy resin can be easily produced with high efficiency by the production method of the present invention and enables molecular design according to the intended performance level described above.

### EXAMPLES

The present invention is specifically described below with reference to examples and comparative examples, and “parts” and “%” below are on a mass basis unless otherwise particularly specified. In addition, melt viscosity at 150° C., GPC, NMR, and MS spectrum were measured under conditions below.
1) Softening point measuring method: JIS K7234
2) GPC: Measurement conditions are as follows.

Measuring apparatus: “HLC-8220 GPC” manufactured by Tosoh Corporation

Column: guard column “HXL-L” manufactured by Tosoh Corporation
“TSK-GEL G2000HXL” manufactured by Tosoh Corporation
“TSK-GEL G2000HXL” manufactured by Tosoh Corporation
“TSK-GEL G3000HXL” manufactured by Tosoh Corporation
“TSK-GEL G4000HXL” manufactured by Tosoh Corporation

Detector: RI (differential refractometer)

Data processing: “GPC-8020 model II version 4.10” manufactured by Tosoh Corporation

Measurement condition:
Column temperature 40° C.
Developing solvent tetrahydrofuran
Flow rate: 1.0 ml/min

Standard: using monodisperse polystyrene below having a known molecular weight according to a measurement manual of “GPC-8020 model II version 4.10 ”.

### (Polystyrene Used)

“A-500” manufactured by Tosoh Corporation

“A-1000” manufactured by Tosoh Corporation

“A-2500” manufactured by Tosoh Corporation

“A-5000” manufactured by Tosoh Corporation

“F-1” manufactured by Tosoh Corporation

“F-2” manufactured by Tosoh Corporation

“F-4” manufactured by Tosoh Corporation

“F-10” manufactured by Tosoh Corporation

“F-20” manufactured by Tosoh Corporation

“F-40” manufactured by Tosoh Corporation

“F-80” manufactured by Tosoh Corporation

“F-128” manufactured by Tosoh Corporation

Sample: prepared by filtering with a microfilter a 1.0 mass % tetrahydrofuran solution in terms of resin solid content (50 μl).
3) ¹³C-NMR: Measurement conditions are as follows.

Apparatus: “JNM-ECA500” manufactured by JEOL Ltd.

Measurement mode: SGNNE (NOE-suppressed 1H complete decoupling method)

Solvent: dimethyl sulfoxide

Pulse angle: 45° pulse

Sample concentration: 30 wt %

Number of acquisitions: 10000
4) MS: JMS-T100GC manufactured by JEOL Ltd.

### Example 1

In a flask provided with a thermometer, a dropping funnel, a cooling tube, a fractionating tube, and a stirrer, 216 parts by mass (1.5 moles) of β-naphthol, 250 parts by mass of isopropyl alcohol, 122 parts by mass (1.50 moles) of a 37% aqueous formalin solution, and 31 parts by mass (0.38 moles) of 49% sodium hydroxide were charged and heated from room temperature to 75° C. under stirring, followed by stirring at 75° C. for 1 hour. Then, 81 parts by mass (0.75 moles) of para-cresol was charged, and the resultant mixture was further stirred at 75° C. for 8 hours. After the end of reaction, the reaction solution was neutralized by adding 45 parts by mass of sodium dihydrogenphosphate, and 630 parts by mass of methyl isobutyl ketone was added, followed by three times of washing with 158 parts of water. Then, drying under heating and pressured pressure was performed to produce 290 parts by mass of cresol-naphthol resin (a-1). FIG. 1 shows a GPC chart of the resultant cresol-naphthol resin (a-1). The cresol-naphthol resin (a-1) had a hydroxyl equivalent of 140 g/eq, and the content of a trifunctional compound represented by structural formula (a) below calculated from the GPC chart was 83.5%.

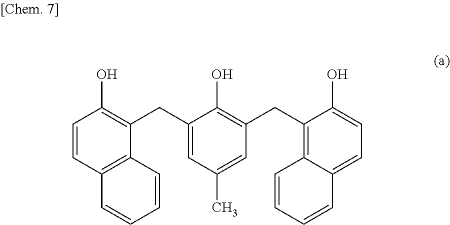 [SMILES: Cc1cc(Cc2c(O)ccc3ccccc23)c(O)c(Cc2c(O)ccc3ccccc23)c1]

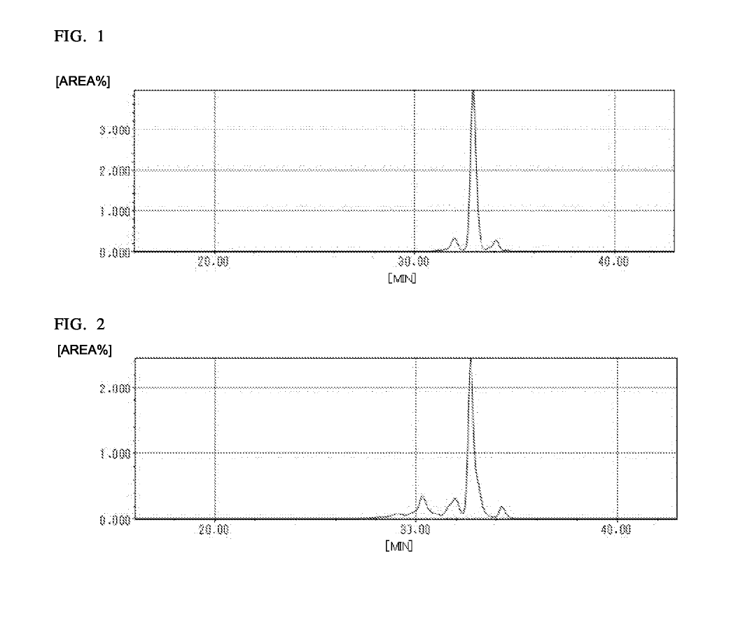

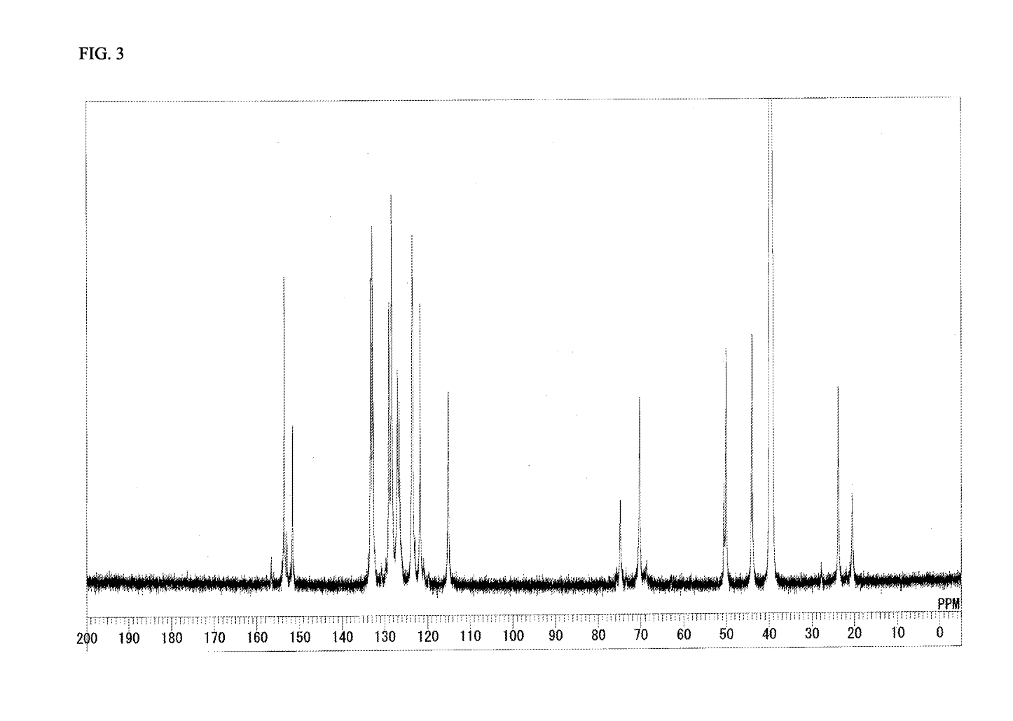

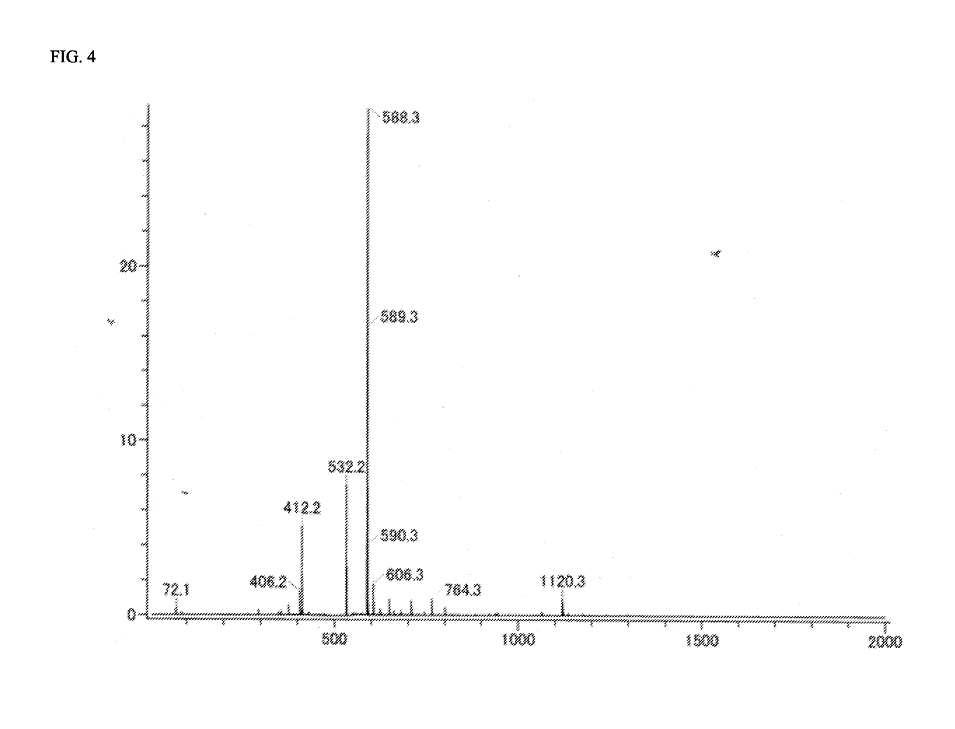

Next, in a flask provided with a thermometer, a cooling tube, and a stirrer, 140 parts by mass (hydroxyl groups: 1.0 equivalent) of the cresol-naphthol resin (a-1) produced by the reaction described above, 463 parts by mass (5.0 moles) of epichlorohydrin, and 53 parts by mass of a n-butanol were charged under nitrogen gas purging and dissolved under stirring. After the temperature was increased to 50° C., 220 parts by mass (1.1 moles) of a 20% aqueous sodium hydroxide solution was added over 3 hours, followed by further reaction at 50° C. for 1 hour. After the end of reaction, stirring was stopped, and an aqueous layer deposited as a lower layer was removed. Then, stirring was started again, and unreacted epichlorohydrin was distilled off at 150° C. under reduced pressure. Then, 300 parts by mass of methyl isobutyl ketone and 50 parts by mass of n-butanol were added to the resultant coarse epoxy resin to prepare a solution. Further, 15 parts by mass of a 10 mass % aqueous sodium hydroxide solution was added to the resultant solution and reacted at 80° C. for 2 hours, and the reaction solution was washed repeatedly 3 times with 100 parts by mass of water until the washing solution showed neutral pH. Next, the system was dehydrated by ezeotropy and micro-filtered, and then the solvent was distilled off under reduced pressure, thereby producing 190 parts by mass of target epoxy resin (A-1). FIG. 2 shows a GPC chart of the resultant epoxy resin (A-1), FIG. 3 shows a NMR chart, and FIG. 4 shows a MS spectrum. The resultant epoxy resin (A-1) had an epoxy equivalent of 240 g/eq. and a softening point of 97° C., and a molecular weight distribution (Mw/Mn) of 1.17. The content of a trifunctional compound represented by structural formula (b) below calculated by the GPC chart was 63.3%, and the content of the dimer (y) represented by the structural formula (2) was 4.8%. Also, a peak at 588 showing the trifunctional compound represented by the structural formula (b) was detected in the MS spectrum.

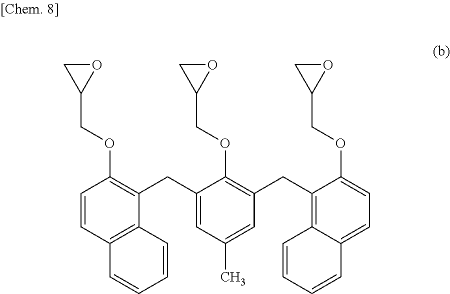 [SMILES: Cc1cc(Cc2c(OCC3CO3)ccc3ccccc23)c(OCC2CO2)c(Cc2c(OCC3CO3)ccc3ccccc23)c1]

### Example 2

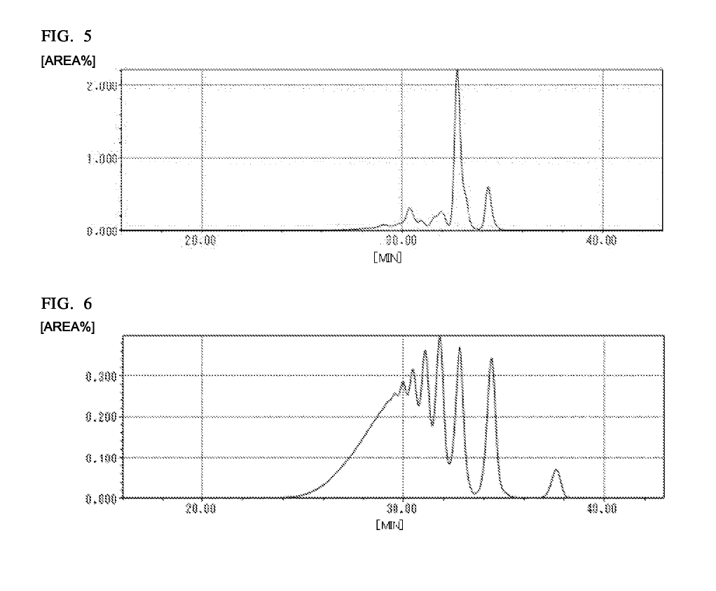

With the exception of changing to 110 parts by mass (1.35 moles) of a 37% aqueous formalin solution and 65 parts by mass (0.60 moles) of para-cresol, 191 parts by mass of epoxy resin (A-2) was produced by the same method as in Example 1. FIG. 5 shows a GPC chart of the resultant epoxy resin (A-2). The resultant epoxy resin (A-2) had an epoxy equivalent of 240 g/eq. and a softening point of 93° C., and a molecular weight distribution (Mw/Mn) of 1.24. The content of a trifunctional compound represented by the structural formula (b) calculated by the GPC chart was 56.4%, and the content of the dimer (y) represented by the structural formula (2) was 13.5%.

### Comparative Synthesis Example 1

In a flask provided with a thermometer, a dropping funnel, a cooling tube, a fractionating tube, and a stirrer, 505 parts by mass (3.50 moles) of β-naphthol, 158 parts by mass of water, and 5 parts by mass oxalic acid were charged and stirred under heating from room temperature to 100° C. over 45 minutes. Then, 177 parts by mass (2.45 moles) of a 42 mass % aqueous formalin solution was added dropwise over 1 hour. After the addition, the resultant mixture was further stirred at 100° C. for 1 hour and then heated to 180° C. over 3 hours. After the end of reaction, the moisture remaining in the reaction system was removed by heating under reduced pressure to produce 498 parts by mass of naphthol resin (a′-1). The naphthol resin (a′-1) had a hydroxyl equivalent of 154 g/eq.

Next, in a flask provided with a thermometer, a cooling tube, and a stirrer, 154 parts by mass (hydroxyl groups: 1.0 equivalent) of the naphthol resin (a′-1) produced by the reaction described above was used under nitrogen gas purging, and 202 parts by mass of epoxy resin (A′-1) was produced by the same method as in Example 1. FIG. 6 shows a GPC chart of the resultant epoxy resin (A′-1). The resultant epoxy resin (A′-1) had an epoxy equivalent of 237 g/eq.

### Examples 3 and 4 and Comparative Example 1

According to compositions shown in Table 1, TD-2090 as a curing agent (phenol novolac resin, hydroxyl equivalent: 105 g/eq) manufactured by DIC Corporation, (A-1) or (A′-1) as an epoxy resin, and 2-ethyl-4-methylimidazole (2E4MZ) as a curing accelerator were mixed, and methyl ethyl ketone was mixed so that the nonvolatile content (N.V.) in each of the final compositions was 58% by mass. Next, a laminate was formed by curing under conditions described below, and evaluated with respect to a coefficient of thermal expansion and change in physical properties by methods described below. The results are shown in Table 1.

### <Conditions for Forming Laminate>

Base material: glass cloth “#2116” (210×280 mm) manufactured by Nitto Boseki Co., Ltd.

Number of plies: 6 Prepregnating condition: 160° C.

Curing conditions: 1.5 hours at 200° C. and 40 kg/cm², thickness after molding: 0.8 mm

### <Change in Heat Resistance Due to Heat History (Change in Heat Resistance: ΔTg): DMA (Difference of Tg Between First Measurement and Second Measurement)>

A temperature (Tg) at which a change in elastic modulus was maximized (the highest rate of change in tan δ) was measured by using a viscoelasticity measuring apparatus (DMA: Rheometrics Inc., solid viscoelasticity measuring apparatus “RSA II”, rectangular tension method: frequency 1 Hz, heating rate 3° C/min) two times under temperature conditions below.

Temperature Condition
First measurement: heating from 35° C. to 275° C. at 3° C/min
Second measurement: heating from 35° C. to 330° C. at 3° C/min

A difference between the measured temperatures was evaluated as ΔTg.

### <Coefficient of Thermal Expansion>

The laminate was cut into a size of 5 mm×5 mm×0.8 mm to form a test piece, and thermomechanical analysis was performed in a compression mode by using the test piece and a thermomechanical analyzer (TMA: SS-6100 manufactured by Seiko Instruments Inc.).

Measurement Conditions
Measurement load; 88.8 mN
Heating rate: two times at 10° C./min
Measurement temperature range: −50° C. to 300° C.

Measurement was performed two times for a same sample under the conditions described above, and a mean coefficient of linear expansion within a temperature range of 40° C. to 60° C. in the second measurement was evaluated as a coefficient of thermal expansion.

TABLE 1

| | | | | Comparative |
|---|---|---|---|---|
| | | Example 3 | Example 4 | Example 1 |
| Epoxy | (A-1) | 69.6 | | |
| resin | (A-2) | | 69.6 | |
| | (A′-1) | | | 69.3 |
| Curing | TD-2090 | 30.4 | 30.4 | 30.7 |
| agent | | | | |

| | | | |
|---|---|---|---|
| 2E4MZ | 0.05 | 0.05 | 0.05 |
| ΔTg (° C.) | 3 | 3 | 15 |
| Coefficient of thermal | 46 | 50 | 60 |
| expansion (ppm) | | | |

Abbreviations in Table 1 are as follows.

TD-2090: phenol novolac-type phenol resin (“TD-20290” manufactured by DIC Corporation, hydroxyl equivalent: 105 g/eq)

2E4MZ: curing accelerator (2-ethyl-4-methylimidazole)

1. An epoxy resin produced by polyglycidyl-etherification of a reaction product of para-cresol, a β-naphthol compound, and formaldehyde, the epoxy resin comprising a trifunctional compound (x) represented by a structural formula (1) below, 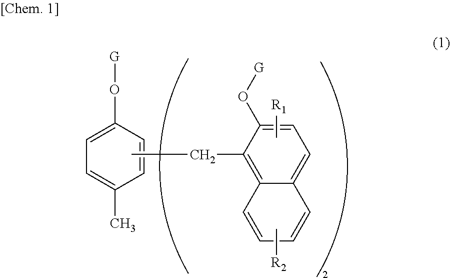
(in the formula, R¹ and R² each independently represent a hydrogen atom, an alkyl group having 1 to 4 carbon atoms, or an alkoxy group having 1 to 4 carbon atoms, and G represents a glycidyl group), and a dimer (y) represented by a structural formula (2) below, 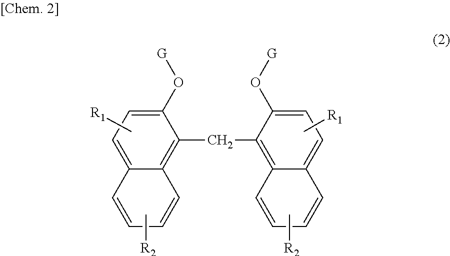
(in the formula, R¹ and R² each independently represent a hydrogen atom, an alkyl group having 1 to 4 carbon atoms, or an alkoxy group having 1 to 4 carbon atoms, and G represents a glycidyl group), and the content of the trifunctional compound (x) is 55% or more in terms of ratio by area in GPC measurement.

2. The epoxy resin according to claim 1, wherein the content of the trifunctional compound (x) is 55% to 95% in terms of ratio by area in GPC measurement.

3. The epoxy resin according to claim 1, wherein the content of the dimer (y) is 1% to 25% in terms of ratio by area in GPC measurement.

4. The epoxy resin according to claim 1, wherein an epoxy equivalent is in a range of 220 to 260 g/eq.

5. The epoxy resin according to claim 1, wherein the softening point is in a range of 80° C. to 140° C.

6. The epoxy resin according to claim 1, wherein a value of molecular weight distribution (Mw/Mn) is in a range of 1.00 to 1.50.

7. A curable resin composition comprising the epoxy resin according to claim 1 and a curing agent as essential components.

8. A cured product produced by curing reaction of the curable resin composition according to claim 7.

9. A printed circuit board produced by mixing an organic solvent with the curable resin composition according to claim 7 to prepare a varnish of the resin composition, impregnating a reinforcing base material with the varnish, and laminating a copper foil and heat-pressure bonding the copper foil.

10. A curable resin composition comprising the epoxy resin according to claim 2 and a curing agent as essential components.

11. A curable resin composition comprising the epoxy resin according to claim 3 and a curing agent as essential components.

12. A curable resin composition comprising the epoxy resin according to claim 4 and a curing agent as essential components.

13. A curable resin composition comprising the epoxy resin according to claim 5 and a curing agent as essential components.

14. A curable resin composition comprising the epoxy resin according to claim 6 and a curing agent as essential components.

15. A cured product produced by curing reaction of the curable resin composition according to claim 10.

16. A cured product produced by curing reaction of the curable resin composition according to claim 11.

17. A cured product produced by curing reaction of the curable resin composition according to claim 12.

18. A printed circuit board produced by mixing an organic solvent with the curable resin composition according to claim 10 to prepare a varnish of the resin composition, impregnating a reinforcing base material with the varnish, and laminating a copper foil and heat-pressure bonding the copper foil.

19. A printed circuit board produced by mixing an organic solvent with the curable resin composition according to claim 11 to prepare a varnish of the resin composition, impregnating a reinforcing base material with the varnish, and laminating a copper foil and heat-pressure bonding the copper foil.

20. A printed circuit board produced by mixing an organic solvent with the curable resin composition according to claim 12 to prepare a varnish of the resin composition, impregnating a reinforcing base material with the varnish, and laminating a copper foil and heat-pressure bonding the copper foil.
